(19) United States
(12) Patent Application Publication
(10) Pub. No.: US 2003/0049546 A1
(43) Pub. Date: Mar. 13, 2003

(54) Charged-particle-beam microlithography reticles including exposure alignment marks associated with individual subfields

(75) Inventor: Shintaro Kawata, Moriya-shi (JP)

Correspondence Address: KLARQUIST SPARKMAN, LLP, One World Trade Center, Suite 1600, 121 S.W. Salmon Street, Portland, OR, 97204-2988, US

(73) Assignee: Nikon Corporation

(21) Appl. No.: 10/236,780

(22) Filed: Sep. 6, 2002

(30) Foreign Application Priority Data
Sep. 13, 2001 (JP) 2001-277455

(51) Int. Cl. G03F 9/00; G03C 5/00

(52) U.S. Cl. 430/5; 430/296; 430/22; 430/942

(57) ABSTRACT

Divided reticles are disclosed for use in charged-particle-beam (CPB) microlithography. The reticles include multiple subfields separated from each other by skirts and struts, and exposure-alignment marks situated in the skirts in association with respective subfields. During exposure, the respective positions of the exposure-alignment marks are detected and appropriate image-position and other corrections are made as required to ensure optimal stitching accuracy of the subfield images on the lithographic substrate. The exposure-alignment marks are formed on the reticle simultaneously with forming the pattern on the reticle using a pattern-drawing apparatus. By facilitating the achievement of optimal stitching of subfield images on the substrate, extreme demands for positional accuracy conventionally placed on the pattern-drawing apparatus are eliminated.

### FIELD

This disclosure pertains to microlithography performed using a charged particle beam such as an electron beam or ion beam. Microlithography is a key technique used in the manufacture of micro-electronic devices such as semiconductor integrated circuits, displays, and the like. More specifically, the disclosure pertains to reticles (sometimes termed “masks” or “transfer masks”) defining a pattern to be transfer-exposed onto a lithographic substrate.

### BACKGROUND

A “reticle” defines the pattern to be projected onto a surface of a lithographic substrate using light (e.g., deep UV light or X-ray light) or a charged particle beam (e.g., electron beam or ion beam). So as to be imprintable with the projected pattern, the substrate is coated with a substance, termed a “resist,” that reacts to exposure or non-exposure in a differential manner.

Reticles are made by forming a desired pattern on a “reticle blank.” With conventional optical microlithography (i.e., microlithography performed using UV light), the entire pattern is defined on the reticle blank as a contiguous whole, allowing the pattern to be “written” on the reticle blank in a raster or vector manner using an electron-beam pattern-drawing apparatus. Due to the importance of achieving pattern continuity and integrity on the reticle, the reticle pattern usually is drawn based solely on the achievable accuracy and precision of the pattern-drawing apparatus, without reliance upon any alignment marks. Alternatively, the pattern may be drawn on the reticle blank through reference to a single alignment mark on the periphery of the reticle blank. In either event, the entire pattern is drawn on the reticle blank in one process, so the accuracy and precision of the pattern-drawing apparatus is extremely important. For example, according to modem standards, the writing tolerance for pattern line width is no more than 10 nm, and the positional accuracy for an entire reticle measuring 200 mm square is 20 nm or less. These specifications impose a tremendous burden on the pattern-drawing apparatus.

Reticles for charged-particle-beam (CPB) microlithography typically are so-called “divided” reticles in which the pattern is divided up into a large number of portions, usually termed “subfields,” each defining a respective portion of the overall pattern. The subfields are exposed, usually in a sequential manner, by individual exposure “shots.” When a pattern is drawn on a divided reticle, the manner in which the pattern is drawn must take into account the division of the pattern into subfields. Accurate placement of the respective pattern portions in the subfields is facilitated by detection of respective alignment marks that are drawn near selected individual subfields at the time of pattern-drawing.

Projection of an entire pattern for a “chip” or the like from a divided reticle onto a substrate is not performed in a single “shot.” Rather, as noted above, the pattern is exposed subfield-by-subfield, wherein each subfield is exposed in a respective shot in a successive manner. The images of the subfields are formed on the substrate in a manner such that the images, despite being separated from one another on the reticle, are contiguous with each other (i.e., “stitched together”) on the substrate. The positions of the subfields are detected using the alignment marks provided on the reticle at time of pattern-drawing, and the respective subfield images are pieced together on the substrate while correcting the respective positions of the subfield images on the basis of the detection results.

Hence, the alignment marks used for projection-exposure of a pattern, defined on a divided reticle, onto a substrate are the same alignment marks formed on the reticle blank during pattern-drawing. The positional accuracy of these alignment marks affects the accuracy with which subfield images are stitched together on the substrate during exposure. As the accuracy with which subfield stitching must be performed has continued to increase, it has become increasingly difficult to achieve a desired stitching accuracy using these alignment marks. In other words, forming the marks on the reticle blank in the conventional manner cannot achieve the newly required positional tolerances for these marks. A noted above, since these alignment marks are formed on the reticle during the process of drawing the entire pattern on the reticle blank, attempting to increase the positional accuracy of the marks on the reticle imposes extreme demands on the pattern-drawing apparatus.

### SUMMARY

In view of the shortcomings of conventional methods and apparatus as summarized above, the present invention provides, inter alia, reticles and methods for manufacturing reticles that allow the currently required increases in stitching accuracy to be obtained without imposing such a heavy burden on the pattern-drawing apparatus.

According to a first aspect of the invention, reticles are provided. An embodiment of such a reticle comprises a plurality of subfields each defining respective elements of the pattern. The reticle also comprises at least one respective exposure-alignment mark pertaining to each subfield, wherein the exposure-alignment marks are formed concurrently with defining the pattern elements. The subject reticle can be configured as a stencil reticle used for charged-particle-beam (CPB) microlithography, or as a continuous-membrane reticle used for CPB microlithography.

Desirably, the subfields are separated one from the other by intervening skirts, wherein the exposure-alignment marks are situated within respective skirts. Each skirt can include a respective strut extending from a center-line of the skirt, wherein the exposure-alignment marks are situated on a side of the reticle opposite a side from which the struts extend from the respective skirts. In this reticle configuration, the exposure-alignment marks generally are situated on a side of the reticle on which the respective pattern elements are formed in the respective subfields.

The accuracy of a pattern-drawing apparatus is determined generally by the accuracy with which pattern portions, projected from the reticle fabricated using the pattern-drawing apparatus, can be stitched together on a lithographic substrate. With an electron-beam pattern-drawing apparatus, the desired accuracy essentially is achieved by making actual drawing manipulations in the direction of deflection of the electron beam used for drawing. Since the maximum deflection of such an electron beam is only a few millimeters, the sizes of the subfields are established so as to be less than the maximum deflection width of the beam. On the resulting reticles, according to this embodiment, the exposure-alignment marks are drawn at the same time as the reticle pattern. Having to draw the exposure-alignment marks at the same time as the reticle pattern does not increase the burden on the drawing apparatus significantly, but achieves the highly beneficial result of the reticle pattern and exposure-alignment marks being positioned very accurately on the reticle.

According to another aspect of the invention, methods are provided for manufacturing a divided reticle having a plurality of subfields. An embodiment of such a method comprises the step of forming, on a reticle blank comprising multiple subfields separated one from another by intervening skirts, respective pattern elements in the subfields. While forming the pattern elements, respective exposure-alignment marks pertaining to the subfields are formed. Desirably, the exposure-alignment marks are formed in the skirts. For CPB microlithography, the reticle blank comprises a reticle membrane, of which respective portions are located in the subfields. In this configuration the exposure-alignment marks can be formed on the reticle membrane on a side of the membrane on which the pattern elements are defined.

With the method summarized above, because the exposure-alignment marks are drawn at the same time that the reticle pattern is drawn, the positions of the exposure-alignment marks can be controlled very accurately and precisely. This drawing of the marks does not place a heavy burden on the electron-beam drawing apparatus, but produces reticles from which projected patterns can be stitched together more accurately and precisely during exposure.

In another method embodiment, a reticle blank is formed that comprises a reticle membrane divided into multiple subfields separated one from the other by intervening skirts. Struts are formed in the reticle blank, wherein the struts extend from respective skirts on a first side of the reticle membrane. Pattern elements are defined in or on the reticle membrane. Simultaneously with defining the pattern elements, exposure-alignment marks are formed in the skirts. Desirably, one or more (more desirably greater than one) respective exposure-alignment marks can be formed corresponding to a respective subfield. The exposure-alignment marks can be formed on a second side of the reticle membrane opposite the first side. The pattern elements can be defined as respective apertures in the reticle membrane, wherein the reticle membrane exhibits forward-scattering properties with respect to an incident charged particle beam. Alternatively, the pattern elements can be defined as respective apertures in a scattering layer applied to a relatively non-scattering reticle membrane.

According to another aspect of the invention, reticles are provided that are manufactured according to any of the method embodiments within the scope of the disclosure.

According to yet another aspect of the invention, microlithography methods in which a pattern, defined on a reticle, is projection-exposed from the reticle onto a photosensitive substrate. An embodiment of such a method comprises producing a reticle, comprising a plurality of subfields each defining respective elements of the pattern, and at least one respective exposure-alignment mark pertaining to each subfield, the exposure-alignment marks being formed concurrently with defining the pattern elements. Using a charged particle beam, the subfields are illuminated individually and respective images of the subfields are projected onto respective locations on the surface of a substrate. The method can further comprise the step of detecting a position of the reticle, before exposing a subfield, by detecting a position of a respective exposure-alignment mark for the subfield. The method can further comprise the step, during exposure of the individual subfields, of correcting the locations onto which the subfield images are projected, wherein the corrections are made based on the detected positions of the exposure-alignment marks.

The foregoing and additional features and advantages of the invention will be more readily apparent from the following detailed description, which proceeds with reference to the accompanying drawings.

### BRIEF DESCRIPTION OF THE DRAWINGS

FIGS. 1(A)-1(B) depict a portion of a representative embodiment of a divided reticle, wherein FIG. 1(A) is an elevational section, and FIG. 1(B) is a plan view.

FIGS. 2(A)-2(F) are elevational sections depicting the results of respective steps in a representative embodiment of a method for manufacturing a reticle.

FIG. 3 is a schematic elevational diagram of an electron-beam microlithography (projection-exposure) apparatus configured to use a reticle as shown, for example, in FIGS. 1(A)-1(B).

### DETAILED DESCRIPTION

The invention is described below in the context of representative embodiments that are not intended to be limiting in any way.

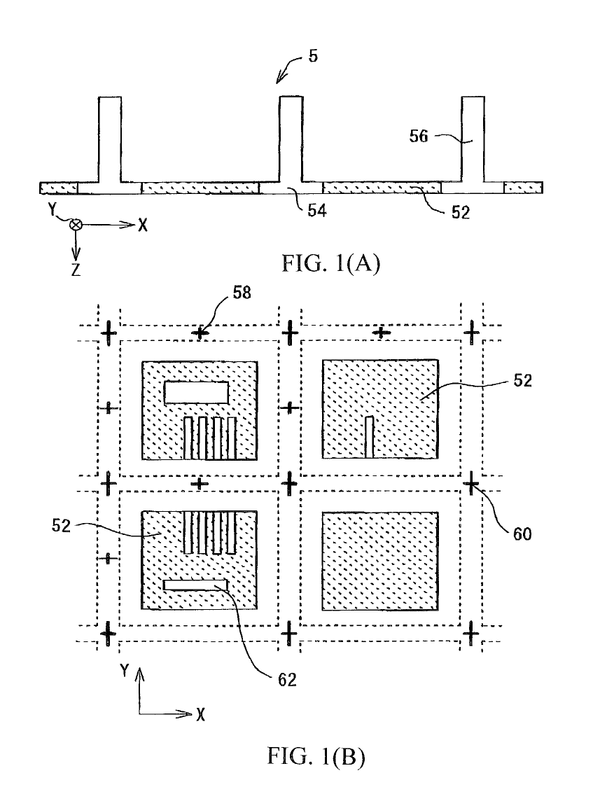

A first representative embodiment is shown in FIGS. 1(A)-1(B), depicting an exemplary portion of a divided reticle 5 in elevational section and plan view, respectively (along the Z-direction). The divided reticle 5 is configured for use in charged-particle-beam (CPB) microlithography (specifically, using an electron beam), and thus comprises multiple subfields 52. The reticle pattern is divided into a corresponding number of pattern portions each including one or more respective pattern elements 62 or portions of pattern elements, wherein each subfield 52 defines a respective pattern portion. The subfields 52 are separated from one another by a non-patterned region 54 termed a “skirt.” Extending in the Z-direction from the center line of each skirt 54 is a respective support column or “strut” 56. The struts 56 collectively define a supporting lattice having a defined thickness in the Z-direction in FIG. 1. The lattice of struts 56 collectively supports the subfields 52, each including a respective extremely thin membrane.

The reticle 5 can be, for example, a “stencil” reticle in which, in each subfield 52, the respective pattern elements are defined as respective apertures (through-holes) in the membrane. The apertures are transmissive to an incident electron beam without causing any significant scattering of electrons of the beam. The membrane regions, made of silicon having a thickness of about 2 μm, are relatively scattering to the electron beam passing therethrough. Alternatively, the reticle 5 can be a “continuous membrane” reticle in which, in each subfield 52, the respective membrane is continuous. The silicon membrane has a thickness of about 0.1 μm and hence imparts substantially no scattering to an incident electron beam. The pattern elements are defined by respective voids in a layer, on the membrane, of a highly scattering material such as a heavy metal or the like.

In FIG. 1(B), exposure-alignment marks 58 are defined on the reticle 5 in respective locations flanking each subfield 52. The marks 58 are defined along the center lines of respective skirts 54 on the surface of the reticle opposite the surface from which the struts 56 extend. In other words, the marks 58 are defined on the same surface on which the pattern elements are defined on the reticle. Each exposure-alignment mark 58 consists of one or more mark elements formed of respective traces of heavy metal on the surface of the skirt or of channels formed by etching the surface of the skirt 54. Formed in a similar manner on the reticle are drawing-alignment marks 60 (FIG. 1(B)) situated at respective locations near subfield comers.

During projection-exposure of the respective pattern portions, formed in individual subfields 52, onto a lithographic substrate (not shown) situated in the +Z-direction from the reticle, an electron beam propagating from upstream of the reticle (from the −Z-direction) is incident on each subfield. The beam, termed an “illumination beam,” has a rectangular transverse profile of which the area is slightly larger than the area of a subfield 52. Thus, during exposure of each subfield 52, the edges of the illumination beam fall within the respective skirt 54.

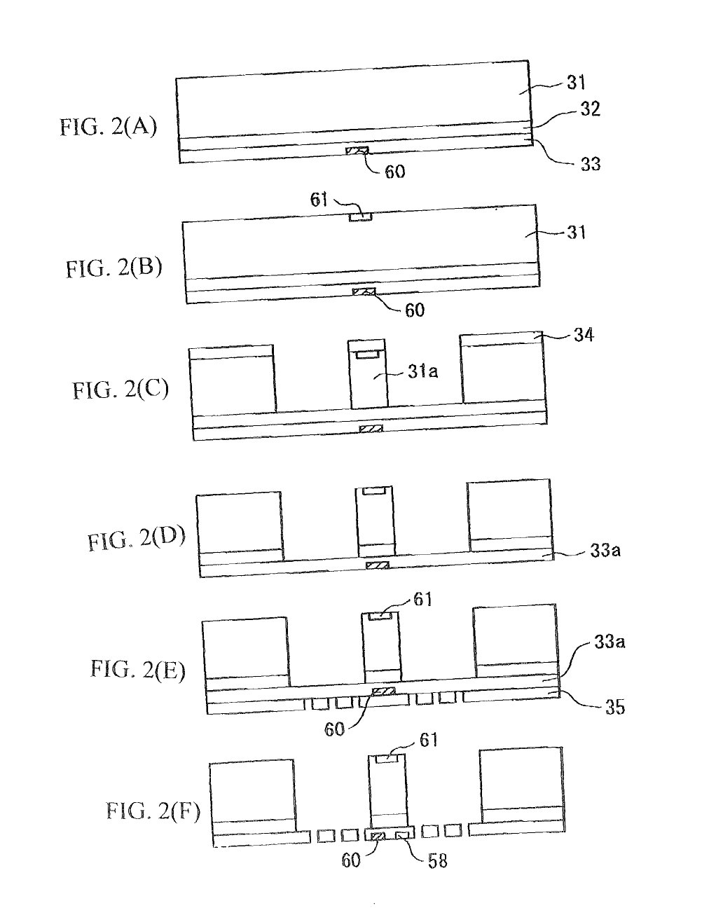

FIGS. 2(A)-2(F) depict, in elevational sections, the results of respective steps in a representative embodiment of a method for manufacturing a reticle such as described above.

First, an SOI (silicon-on-insulator) substrate is prepared, comprising a support-silicon substrate 31, a silicon oxide layer 32, and a silicon “active” layer 33. The SOI substrate is produced using conventional methods (FIG. 2(A)). Next, alignment marks 60 are formed at selected locations on the “active” layer 33 (FIG. 2(B)) at which respective struts will be formed. The alignment marks 60 are destined for use in positional alignments performed during a later electron-beam pattern-drawing step.

Next, the support silicon 31 is coated with a resist. The resist is imprinted with patterns at selected locations corresponding to respective positions at which exposure-alignment marks will be formed. Imprinting is performed using the electron-beam pattern-drawing apparatus. The exposed resist is cured to form a dry-etching mask. Based on the mask, the support silicon 31 is dry-etched to form respective alignment marks 61 (FIG. 2(B)) destined for use during a later pattern-drawing step.

Locations on the support silicon at which support struts will be located are protected by application of a suitable resist 34. The resist 34 is patterned appropriately and used as a dry-etching mask during a dry-etching step that removes exposed support silicon down to the silicon oxide layer 32, thereby forming the support struts 31a (FIG. 2(C)). Next, the silicon oxide layer 32 exposed on either side of the support column 31a is removed by wet etching (FIG. 2(D)), leaving the “active” layer 33 configured as a contiguous membrane 33a.

The membrane 33a is coated with a resist 35, and a reticle pattern is “drawn” on the surface of the membrane 33a by a pattern-drawing apparatus that refers to the alignment marks 60, 61 for proper positioning of the pattern elements within respective subfields (FIG. 2(E)). During this step, exposure-alignment marks are also drawn on the surface of the membrane 33a. The patterned resist 35 is cured and, using the cured resist as a mask, the membrane 33a is dry etched, thereby forming apertures in the membrane 33a corresponding to respective pattern elements. Also formed during this dry-etching step are the exposure-alignment marks 58 (FIG. 2(F)). Thus, drawing of the exposure-alignment marks 58 is performed at the same time as drawing of the reticle pattern. This drawing is performed within the range of maximum electron-beam deflection in the pattern-drawing machine, with reference to the drawing-alignment marks 60, 61. As a result, the drawing of the pattern elements and exposure-alignment marks 58 proceeds under conditions in which positional control is achieved with extremely high accuracy and precision. This process reduces the burden, compared to conventional processes, on the electron-beam pattern-drawing apparatus and produces reticles with which the stitching accuracy can be increased during actual lithographic exposure performed using the reticles.

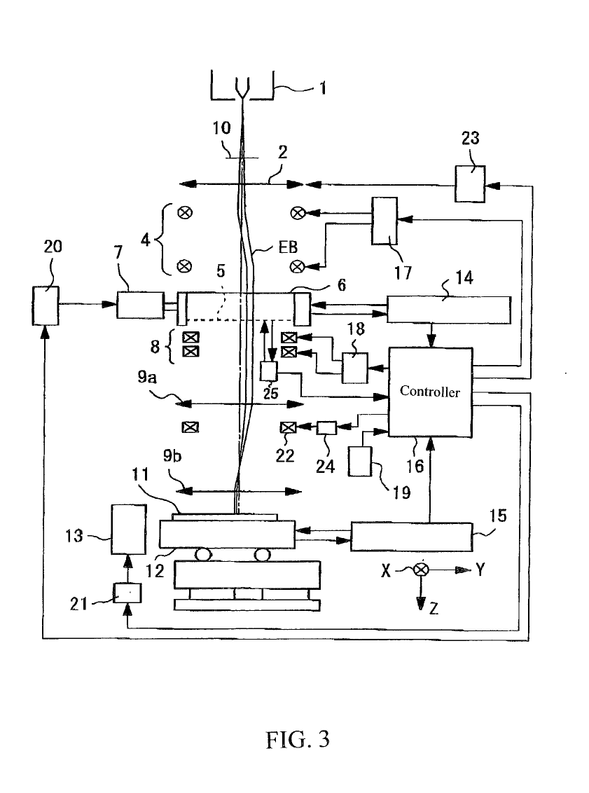

An embodiment of a CPB microlithography (projection-exposure) apparatus utilizing a reticle manufactured as described above, is shown in FIG. 3. Specifically, the apparatus of FIG. 3 is configured to perform electron-beam projection-exposure of the pattern defined on the reticle 5 shown in FIG. 1. The FIG.-3 apparatus comprises an electron gun 1 located at the extreme upstream end of the system. The electron gun 1 produces an electron beam EB (“illumination beam”) that propagates in a downstream direction (downward in the figure). Downstream of the electron gun is a beam-trimming aperture 10 that trims the lateral edges of the illumination beam EB to a desired transverse profile (e.g., rectangular or square). The trimmed illumination beam then passes through a condenser lens 2 that focuses the illumination beam EB on the reticle 5. The illumination beam EB passing through the condenser lens 2 is guided to selected individual subfields 52 of the reticle 5 by a subfield-selection deflector 4. The reticle 5 is mounted on a reticle stage 6 that moves the reticle 5 horizontally as required in the X- and Y-directions. Movement of the reticle stage 6 is imparted by an actuator 7 powered by a respective driver 20.

Portions of the illumination beam passing through the reticle 5 carry an aerial image of the illuminated subfield; hence, the beam downstream of the reticle 5 is an “imaging” or “patterned” beam. The patterned beam passes a deflector 8 that deflects the patterned beam as required in the X- and Y-directions to cause the patterned beam to be incident at a desired location on the substrate 11. The aerial image carried by the patterned beam is focused on the surface of the substrate 11 by passage through projection lenses 9a, 9b. The projection lenses 9a, 9b collectively have a “reduction” (demagnification) factor ¼, for example, by which is meant that the image formed on the substrate 11 is 4× smaller than the corresponding pattern on the reticle 5.

In the apparatus of FIG. 3, item 25 is a detector used for detecting the exposure-alignment marks formed on the skirt 54 of the reticle 5. Item 22 is a corrective-optical system situated and configured to perform corrections of pattern-image magnification, image rotation, and astigmatism, based on data produced by the detector 25. The detector 25 can be any of various detectors used, for example, in FIA (Field Image Alignment), LSA (Laser Step Alignment), LIA (Laser Interferometric Alignment) alignment devices.

For exposure, the substrate 11 (e.g., resist-coated semiconductor wafer) is mounted on a substrate stage 12 that moves the substrate horizontally in the X- and Y-directions. Movement of the substrate stage 12 is imparted by an actuator 13 under the control of a driver 21. The respective positions of the reticle stage 6 and substrate stage 12 in the X- and Y-directions are detected by respective laser interferometers 14, 15 (or analogous detectors) that route respective position data to a controller 16.

The controller 16 calculates the actual positions of the exposure-alignment marks 58 on the basis of detection data routed to the controller 16 from the detector 25 and the position detector 14. The controller 16 also routes position-correction signals as required to the drivers 23, 17, 18, 24 for the condenser lens 2, the deflector 4, the deflector 8, and the corrective optical system 22, respectively. Correction of the condenser lens 2 and deflector 4 results in correction of the irradiation position at which the illumination beam EB irradiates a selected subfield 52 of the reticle 5 as well as correction of the transverse profile of the beam. Correction of the deflector 8 and corrective optical system 22 yields positional corrections of the pattern image as projected onto the substrate 11.

Although the corrective optical system 22 is depicted as a single lens in FIG. 3, it actually comprises a magnification-correction lens, a rotation-correction lens, and an astigmatism-correction lens.

Item 19 in FIG. 3 is an input device used for inputting exposure data to the controller 16.

In an example, a stencil reticle, having dimensions of 200 mm square and a membrane thickness of 3 μm was used. The pattern and exposure-alignment marks were drawn on the reticle using an electron-beam pattern-drawing apparatus exhibiting a positional accuracy, at the maximum deflection width of the electron drawing beam, of 16 nm or less. When the pattern on the reticle was projection-exposed onto a substrate using an electron-beam microlithography apparatus as shown in FIG. 3, the realized stitching accuracy was about 7 nm, taking the mean sum of squares of the alignment accuracy of the microlithography apparatus itself (6 nm) and the positional accuracy of the reticle (16 nm/4=4 nm). By thus using a reticle on which the pattern and the exposure-alignment marks were positioned very accurately, and by performing projection-exposure while detecting the positions of the exposure-alignment marks on the reticle, it was possible to achieve a highly accurate stitching accuracy on the substrate.

As described above, a reticle pattern and exposure-alignment marks are positioned very accurately on the reticle. If the pattern-drawing apparatus is not up to drawing the entire pattern with optimal accuracy, so long as the apparatus can draw the respective pattern portions in the subfields, high-accuracy reticles nevertheless can be produced.

Whereas the invention has been described in connection with multiple representative embodiments, it will be understood that the invention is not limited to those embodiments. On the contrary, the invention is intended to encompass all modifications, alternatives, and equivalents as may be included within the spirit and scope of the invention, as defined by the appended claims.

What is claimed is:

1. A reticle, comprising:
a plurality of subfields each defining respective elements of the pattern; and
at least one respective exposure-alignment mark pertaining to each subfield, the exposure-alignment marks being formed concurrently with defining the pattern elements.

2. The reticle of claim 1, configured as a stencil reticle used for charged-particle-beam microlithography.

3. The reticle of claim 1, configured as a continuous-membrane reticle used for charged-particle-beam microlithography.

4. The reticle of claim 1, wherein:
the subfields are separated one from the other by intervening skirts; and
the exposure-alignment marks are situated within respective skirts.

5. The reticle of claim 4, wherein:
each skirt includes a respective strut extending from a center line of the skirt; and
the exposure-alignment marks are situated on a side of the reticle opposite a side from which the struts extend from the respective skirts.

6. The reticle of claim 5, wherein the exposure-alignment marks are situated on a side of the reticle on which the respective pattern elements are formed in the respective subfields.

7. A method for manufacturing a divided reticle having a plurality of subfields, the method comprising:
on a reticle blank comprising multiple subfields separated one from another by intervening skirts, forming respective pattern elements in the subfields; and
while forming the pattern elements, forming respective exposure-alignment marks pertaining to the subfields.

8. The method of claim 7, wherein the exposure-alignment marks are formed in the skirts.

9. The method of claim 8, wherein:
the reticle blank comprises a reticle membrane, respective portions of which are located in the subfields; and
the exposure-alignment marks are formed on the reticle membrane on a side of the membrane on which the pattern elements are defined.

10. A method for manufacturing a divided reticle, comprising:
forming a reticle blank comprising a reticle membrane divided into multiple subfields separated one from the other by intervening skirts;
forming struts in the reticle blank, the struts extending from respective skirts on a first side of the reticle membrane;
defining pattern elements in or on the reticle membrane; and
simultaneously with defining the pattern elements, forming exposure-alignment marks in the skirts.

11. The method of claim 10, wherein at least one respective exposure alignment mark is formed corresponding to a respective subfield.

12. The method of claim 10, wherein the exposure-alignment marks are formed on a second side of the reticle membrane opposite the first side.

13. The method of claim 10, wherein the pattern elements are defined as respective apertures in the reticle membrane, the reticle membrane exhibiting forward-scattering properties with respect to an incident charged particle beam.

14. The method of claim 10, wherein the pattern elements are defined as respective apertures in a scattering layer applied to a relatively non-scattering reticle membrane.

15. A reticle, manufactured according to the method recited in claim 7.

16. A reticle, manufactured according to the method recited in claim 10.

17. A microlithography method in which a pattern, defined on a reticle, is projection-exposed from the reticle onto a photosensitive substrate, the method comprising:
producing a reticle, comprising a plurality of subfields each defining respective elements of the pattern, and at least one respective exposure-alignment mark pertaining to each subfield, the exposure-alignment marks being formed concurrently with defining the pattern elements; and
using a charged particle beam, illuminating the subfields individually and projecting respective images of the subfields onto respective locations on the surface of a substrate.

18. The method of claim 17, further comprising the step of detecting a position of the reticle, before exposing a subfield, by detecting a position of a respective exposure-alignment mark for the subfield.

19. The method of claim 18, further comprising the step, during exposure of the individual subfields, of correcting the locations onto which the subfield images are projected, the corrections being made based on the detected positions of the exposure-alignment marks.
